(19) United States
(12) Patent Application Publication
(10) Pub. No.: US 2006/0223280 A1
(43) Pub. Date: Oct. 5, 2006

(54) Method for manufacturing semiconductor device and semiconductor device

(75) Inventor: Kenji Ueda, Suita (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/376,189

(22) Filed: Mar. 16, 2006

(30) Foreign Application Priority Data
Mar. 29, 2005 (JP) 2005-095926

(51) Int. Cl. H01L 21/76

(52) U.S. Cl. 438/435

(57) ABSTRACT

In the present invention, trenches are formed on a principal surface of a silicon substrate; a first insulating film is formed on an entire surface of the silicon substrate including trenches so as not to bury the trenches; a second insulating film burying the trenches and covering the principal surface of the silicon substrate is formed; and planarization is performed by polishing a surface of the second insulating film until the first insulating film formed on the principal surface of the silicon substrate is exposed. Here, as the first insulating film, a silicon oxide film whose surface or a portion in vicinity to the surface is silicon-rich is formed and as the second insulating film, a silicon oxide film is formed.

### BACKGROUND OF THE INVENTION

1. Field of the Invention

The present invention relates to a method for manufacturing a semiconductor device and to a semiconductor device, and more particularly, to a method for manufacturing a semiconductor device, in which STI (Shallow Trench Isolation) is employed for element isolation.

2. Description of the Background Art

In recent years, in order to attain miniaturization and higher integration of a semiconductor device, STI has come to be employed, replacing LOCOS (Local Oxidization of Silicon) which has been so-far-used as an element isolation method. In STI, trenches on a principal surface of a semiconductor substrate are formed, an isolation film such as an oxide film is buried in the trenches, and there after planarization is performed to form element isolation portions. In STI, because the trenches having precipitous side surfaces against the principal surface of the semiconductor substrate can be formed, lateral spreads on the element isolation portions, such as a bird's beak which is a problem in LOCOS, are ameliorated, realizing as miniaturized element isolation as designed.

Hereinafter, the conventional method for forming the element isolation in which STI is employed will be described with reference to FIG. 4. FIG. 4 shows sectional views of a semiconductor substrate at respective steps of forming element isolation portions by using STI. FIG. 4(a) shows a sectional view where a silicon nitride film 23 has been formed on a principal surface of a silicon substrate 21 as a semiconductor substrate, with a silicon oxide film 22 interposed therebetween.

FIG. 4(b) shows a sectional view where a trench 24a and a trench 24b have been formed on the principal surface of the silicon substrate 21. In order to obtain the silicon substrate 21 in this state, by using the heretofore known etching technique in which photo resist is used, patterning of the silicon nitride film 23 and the silicon oxide film 22 into desired shapes is performed. Next, by using the patterned silicon nitride film 23a and the silicon oxide film 22a as masks, etching on the silicon substrate 21 is performed. Thereby the trench 24a and the trench 24b serving as the element isolation portions are formed.

FIG. 4(c) shows a sectional view where a silicon oxide film 25 has been formed so as to cover an entire surface of the silicon substrate 21. In order to obtain the silicon substrate 21 in this state, by using thermal oxidation, silicon oxide films 26a and 26b are formed inside the trenches 24a and 24b. Then by using CVD (Chemical Vapor Deposition), the trenches 24a and 24b with the silicon oxide films 26a and 26b formed are buried and the silicon oxide film 25 covering the principal surface of the silicon substrate 21 is formed.

FIG. 4(d) shows a sectional view where planarization has been performed on a surface of the silicon substrate 21. By using CMP (Chemical Mechanical Polish), the planarization is performed by polishing the surface of the silicon oxide film 25. Because a polishing rate of the silicon nitride film 23a is markedly lower than and one several tenth of that of the silicon oxide film 25, the silicon oxide film 25 covering the principal surface of the silicon substrate 21 is completely removed and once the silicon nitride film 23a patterned in a desired shape is exposed, the planarization is finished with the silicon nitride film 23a serving as a polishing stopper. Thereby the surface of the silicon substrate 21 is planarized and insides of the trenches 24a and 24b are buried with the silicon oxide films 25a and 25b.

Here, when the silicon oxide film 25 is removed from the surface of the silicon substrate 21 by using CMP, if a surface area of the element isolation portion is too large, the surface of the silicon nitride film 25 is excessively polished and thereby a surface position of the silicon nitride 25 is lower than a surface position of the silicon nitride film 23a, being lowered than a position of the surface of the silicon substrate 21. In order to avoid this phenomenon, there has been proposed a method for uniformly polishing the silicon oxide film 25 on the entire surface of the silicon substrate 21 by selectively removing the silicon oxide film 25 prior to the polishing (for example, refer to Japanese Laid-Open Patent Publication No. 1993-335290 and Japanese Laid-Open Patent Publication No. 1993-335291). At the step shown in FIG. 4(d), although instead of CMP, etch back in which overall etching on the surface of the silicon oxide film 25 is performed by using a dry etching technique may be employed, CMP has generally been employed for ensuring the planarization of the surface of the silicon oxide film 25 remaining on the trenches 24a and 24b.

FIG. 4(e) shows a sectional view where element isolation portions 40a and 40b have been formed on the principal surface of the silicon substrate 21. The element isolation portions 40a and 40b are obtained through etching-removal of the silicon nitride film 23a and the silicon oxide film 22a remaining after the planarization has been performed. Hereinafter, the element isolation portions 40a and 40b formed by STI in this manner are referred to as the element isolation portions 40a and 40b having STI structures.

However, in the above-mentioned method for forming the element isolation portions 40a and 40b, since the silicon nitride film 23a is used as the CMP polishing stopper, many steps such as those of forming the silicon nitride film 23, patterning, and further removing the silicon nitride film 23a are required, not only increasing manufacturing time of the semiconductor but also raising manufacturing cost.

### SUMMARY OF THE INVENTION

In order to solve the above-mentioned problems, the present invention is directed to a method for manufacturing a semiconductor device, in which element isolation is performed by using STI. In the manufacturing method of the semiconductor device, first, trenches are formed on a principal surface of the semiconductor device. Next, a first insulating film is formed on an entire surface of the semiconductor device including the trenches so as not to bury the trenches. Next, a second insulating film burying the trenches and covering the principal surface of the semiconductor substrate is formed on the first insulating film. Next, planarization on the second insulating film is performed by polishing the second insulating film until the first insulating film formed on the principal surface of the semiconductor substrate is exposed. Here, as the first insulating film, a silicon oxide film whose surface or a portion in vicinity to the surface is silicon-rich is formed and as the second insulating film, a silicon oxide film is formed. Thereby, when the planalization on the surface of the second insulating film is performed, the silicon-rich silicon oxide film whose polishing rate is sufficiently lower than that of the silicon oxide film can be used as a polishing stopper. Because the silicon-rich silicon oxide film can be used as an insulating film for burying the trenches, fiddly processing required for forming a silicon nitride film which has been used as a polishing stopper in the above-mentioned conventional example is not necessary and element isolation portions having a STI structure is easily formed.

In addition, because the polishing rate of the silicon-rich silicon oxide film is, as described above, sufficiently lower than that of the silicon oxide film, the silicon-rich silicon oxide film is not needed to be silicon-rich in an entirety thereof and may be formed so that a composition ratio of silicon is reduced in a continuous or phased manner from the surface thereof toward the surface of the semiconductor substrate.

In addition, the first insulating film may be of a laminated structure in which a first silicon oxide film having contact with inner walls of the trenches is formed and next, a second silicon-rich silicon oxide film is formed on the first silicon oxide film. The first insulating film having the above-mentioned structure allows formation of a highly reliable gate oxide film, a reduction in a leak current, and miniaturized element isolation portions, thereby realizing a more highly reliable and more miniaturized semiconductor device.

The first insulating film may be formed by forming a silicon oxide film and implanting silicon ions on a surface of this silicon oxide film.

Although it is preferable that the first insulating film is formed, while applying a high-frequency power on the semiconductor substrate, by using high-density plasma CVD, the first insulating film may be formed by using thermal CVD.

After the planarization on the surface of the second insulating film, a step of removing the first insulating film exposed on the semiconductor substrate using a mixed solution of hydrofluoric acid and nitric acid may be included. Because the mixed solution of hydrofluoric acid and nitric acid allows higher-rate etching on the silicon-rich silicon oxide film than on the silicon oxide film, only the silicon-rich silicon oxide film can be easily removed.

Furthermore, the present invention is directed to a semiconductor device formed by the method described above. The semiconductor device comprises: a semiconductor substrate; a plurality of elements formed on a principal surface of the semiconductor substrate; trenches, for element-isolating the adjacent elements respectively, formed on the principal surface of the semiconductor substrate; and element isolation portions formed by burying an insulating film in the trenches. Here, the insulating film comprises a silicon oxide film, as a first insulating film, whose surface or a portion in vicinity to the surface is silicon-rich and is formed so as not to bury the trenches, and a silicon oxide film, as a second insulating film, formed so as to bury the trenches and cover the principal surface of the semiconductor substrate.

It is preferable that in the first insulating film, a composition ratio of silicon is reduced in a continuous or phased manner from the surface thereof toward the surface of the semiconductor substrate. For example, the first insulating film having the structure described above comprises a first silicon oxide film formed so as to have contact with inner walls of the trenches and a second silicon oxide film whose surface or a portion in vicinity to the surface is silicon-rich.

As described above, according to the present invention, using the silicon-rich silicon oxide film, instead of the silicon nitride film as a polishing stopper used when using CMP, allows the element isolation portions having the STI structure to be formed with ease and low cost.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows sectional views illustrating steps of manufacturing element isolation portions according to a first embodiment of the present invention;

FIG. 2 shows sectional views illustrating steps of manufacturing element isolation portions according to a second embodiment of the present invention;

FIG. 3 shows sectional views illustrating steps of manufacturing element isolation portions according to a fourth embodiment of the present invention; and

FIG. 4 shows section views illustrating steps of manufacturing element isolation portions having a conventional STI structure.

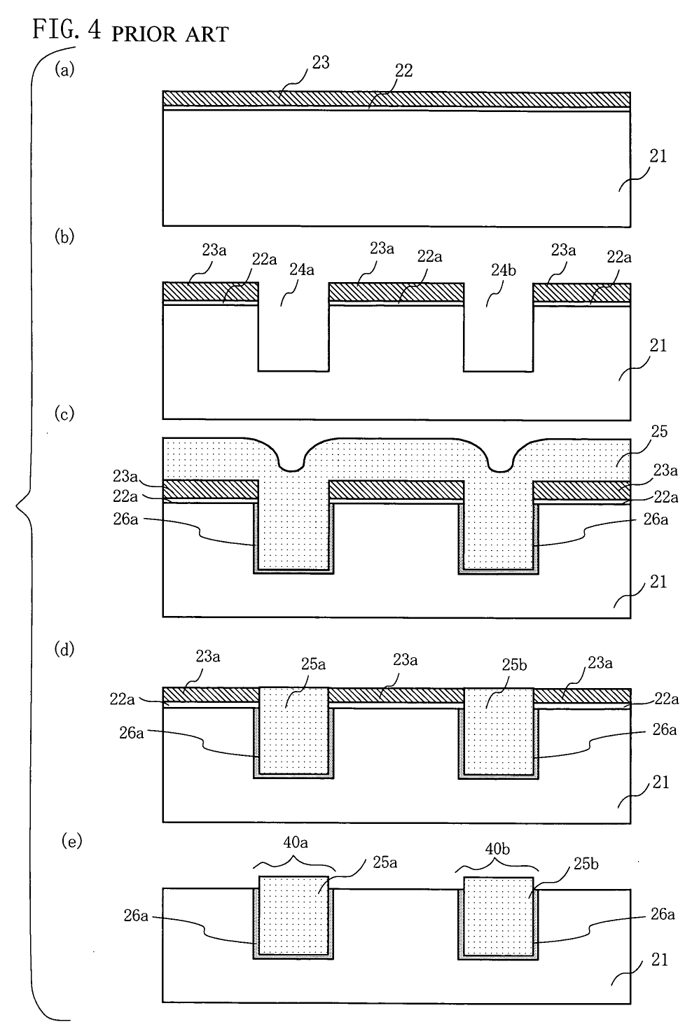

### DESCRIPTION OF THE PREFERRED EMBODIMENTS

### First Embodiment

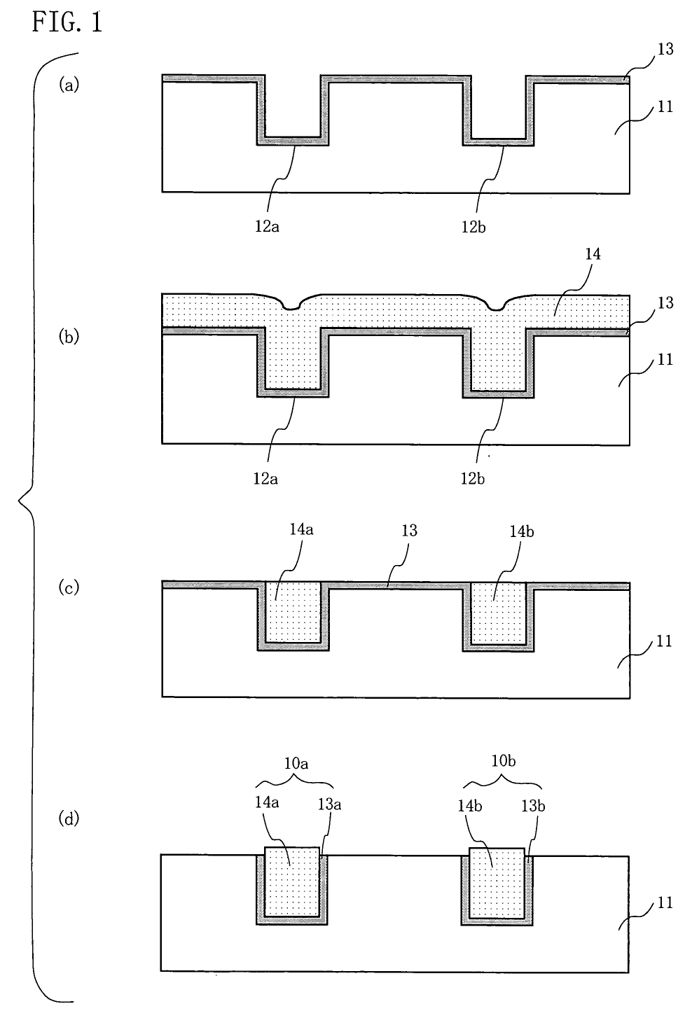

Hereinafter, a manufacturing method of a semiconductor device according to a first embodiment of the present invention will be described, with reference to a specific example. FIG. 1 shows sectional views of a semiconductor substrate at respective steps of forming element isolation portions having the STI structures. FIG. 1(a) shows a sectional view where trenches 12a and 12b have been formed on a semiconductor substrate and specifically, where a silicon-rich silicon oxide film 13, as a first insulating film, has been formed so as to cover an entire surface of a silicon substrate 11. In order to obtain the silicon substrate 11 in this state, by using a photolithography technique and a dry etching technique, trenches 12a and 12b each having a depth of 400 nm and a minimum opening width 100 nm is formed on a principal surface of the silicon substrate.

Next, by using high density plasma CVD equipment, a silicon oxide (SiO₂) film 13 which contains a stoichiometrically larger quantity of silicon than that of an ordinary silicon oxide film, i.e., a so-called silicon-rich silicon oxide film, is formed so as to cover the principal surface of the silicon substrate 11 including the trenches 12a and 12b. The silicon-rich silicon oxide film 13 is formed so as to have a film thickness with which the trenches are not buried, which is thinner than 400 nm of the each depth of the trenches 12a and 12b. Here, a silicon-rich silicon oxide film 13 having a film thickness of 20 nm is formed. The silicon-rich silicon oxide film having this film thickness is formed, for example, in a way below described. First, approximately 50 sccm of silane (SiH₄) gas, approximately 50 sccm of oxygen (O₂) gas, and approximately 100 sccm of argon (Ar) gas are introduced into a reaction chamber (not shown). In the reaction chamber where pressure is approximately 0.3 Pa and a film forming temperature is approximately 400 degrees C., 2000 W of microwave output and 2000 W of high-frequency power are supplied on the silicon substrate 11. Thereby the silicon-rich silicon oxide film 13 having a film thickness of 20 nm is formed on the entire surface of the silicon substrate 11 with the trenches 12a and 12b formed thereon. Whether the obtained silicon oxide film is silicon-rich can be determined through measuring a refractive index of the silicon oxide film. In general, the silicon oxide film 13 having the refractive index of 1.46 or more is determined as being silicon-rich.

In order to form the silicon-rich silicon oxide film 13, an influx ratio of the silane gas to the oxygen gas has to be low, with the ratio of the silane gas to the oxygen gas being for example, approximately from “1 to 0.5” to “1 to 2.0”. However, when film formation is performed by using the plasma CVD equipment, these film formation conditions are greatly influenced by a structure of the reaction chamber. Therefore, conditions for forming the silicon-rich silicon oxide film 13 are not limited to the above-mentioned conditions.

FIG. 1(b) shows a sectional view where the trenches 12a and 12b on the silicon-rich silicon oxide film 13 are buried and a silicon oxide film 14, as a second insulating film covering the principal surface of the silicon substrate 11, is formed. The silicon oxide film 14 is an ordinary silicon oxide film, not silicon-rich. The formation of the silicon oxide film 14 can be performed by using the same reaction chamber as used for the formation of the silicon-rich oxide film 13, following the formation of the silicon-rich silicon oxide film 13.

The silicon oxide film 14 is formed, for example, in a way described below. First, a silane gas and an oxygen gas, as reaction gases, are introduced into the reaction chamber (not shown) used in the above-mentioned way of the formation, with an approximate influx ratio of 1 portion of the silane gas to approximately 3 or more portion of the oxygen gas. In the reaction chamber where pressure is approximately 0.3 Pa and a film formation temperature is approximately 400 degrees C., 2000 W of microwave output and 2000 W of high-frequency power are supplied on the silicon substrate 11. Thereby the silicon oxide film 14 is formed on the silicon-rich silicon oxide film 13.

FIG. 1(c) shows a sectional view where planarization has been performed on the silicon oxide film 14 by using CMP. When planarization is performed on a surface of the silicon oxide film 14 covering the silicon substrate 11 by using CMP, as polishing proceeds, the silicon-rich silicon oxide film 13 formed on the principal surface of the silicon substrate 11 is being exposed. Because a polishing rate of the silicon-rich silicon oxide film 13 is much lower than and one several tenth of that of the silicon oxide film 14, the silicon-rich oxide film 13 serves as a polishing stopper, stopping the polishing of the silicon oxide film 14. Thereby the silicon oxide film 14 formed on the principal surface of the silicon substrate 11 is completely removed and the silicon oxide films 14a and 14b remain only inside of the trenches 12a and 12b. The silicon oxide films 14a and 14b function as element insulating films. In general, a ratio of a polishing rate of the silicon-rich silicon oxide film 13 to a polishing rate of the silicon oxide film 14 is hardly affected by a kind of slurry.

FIG. 1(d) shows a sectional view where the silicon-rich silicon oxide film 13 formed on the principal surface of the silicon substrate 11 has been removed. In order to obtain the silicon substrate 11 in this state, etching, using the mixed solution of hydrofluoric acid and nitric acid, is preferably performed on the silicon-rich silicon oxide film 13. Because an etching rate, using the mixed solution of hydrofluoric acid and nitric acid, of the silicon-rich silicon oxide film 13 is higher than that of the silicon oxide film 14, when the entire surface of the silicon substrate 11 in the state shown in FIG. 1(c) is etched, reduced etching amounts of the silicon films 14a and 14b which are etched at the same time when the silicon-rich silicon oxide film 13 is etched can be obtained, enabling favorable removal of the silicon-rich silicon oxide film 13 formed on the principal surface of the silicon substrate 11. Thus highly reliable element isolation portions 10a and 10b are formed on the principal surface of the silicon substrate 11.

As described above, according to the present embodiment, by using, as an insulating film used when forming the element isolation portions 10a and 10b, a laminated film where the silicon-rich silicon oxide film 13 and the ordinary silicon oxide film 14 have been deposited in a successive manner, the silicon-rich silicon oxide film 13 can be utilized as the polishing stopper. Thereby the formation of more highly reliable element isolation portions 10a and 10b can be realized, with more ease and lower cost, than the formation of element isolation portions where a nitride film is used as a polishing stopper as above described in the conventional example. In addition, because the silicon-rich silicon oxide film 13 and the silicon oxide film 14 can be successively formed in the same reaction chamber, manufacturing efficiency is greatly enhanced.

Although at the above described step shown in FIG. 1(a), the high-density plasma CVD is used for forming the silicon-rich silicon oxide film 13 while applying the high-frequency power on the silicon substrate 11, CVD is not limited to the high-density plasma CVD, and thermal CVD may be used for forming the silicon-rich silicon oxide film 13. In the thermal CVD, the silicon-rich silicon oxide film 13 is formed by controlling a ratio of influx amounts of the silane gas and the oxygen gas by using thermal CVD equipment.

In addition, although in the above description, the silicon-rich silicon oxide film 13 which is silicon rich in the entirety thereof is exemplified as the first insulating film, a silicon-rich silicon oxide film 13 is not limited to this and at least a surface or a portion in vicinity to the surface may be silicon-rich. This is because a CMP polishing rate of the silicon-rich silicon oxide film is markedly high as compared with that of the ordinary silicon oxide film. Therefore, the first insulating film is not required to be a silicon oxide film 13 which is silicon rich through the entirety thereof and may be a silicon-rich silicon oxide film 13 which is constructed so that silicon composition thereof is reduced in a continuous or phased manner from the surface thereof toward the surface of the silicon substrate 11. And the first insulating film may be of a laminated structure comprising a first silicon oxide film having contact with inner walls of the trenches 12a and 12b and a second silicon-rich silicon oxide film formed on this first silicon oxide film. Here, the first silicon oxide film is an ordinary silicon oxide film.

### Second Embodiment

Hereinafter, a method for manufacturing a semiconductor device according to a second embodiment of the present invention will be described with reference to a specific example. In the present embodiment, the method for manufacturing the semiconductor device in which a first insulating film, instead of the silicon-rich silicon oxide film 13 in accordance with the first embodiment, is of a laminated structure comprising a first silicon oxide film having contact with inner walls of trenches 12a and 12b and a second silicon-rich silicon oxide film formed on the first silicon oxide film will be described. Since a structure of the semiconductor device in the present embodiment has a substantially same structure of the semiconductor device in accordance with the fist embodiment, only differences between the first and second embodiments will be described hereinafter.

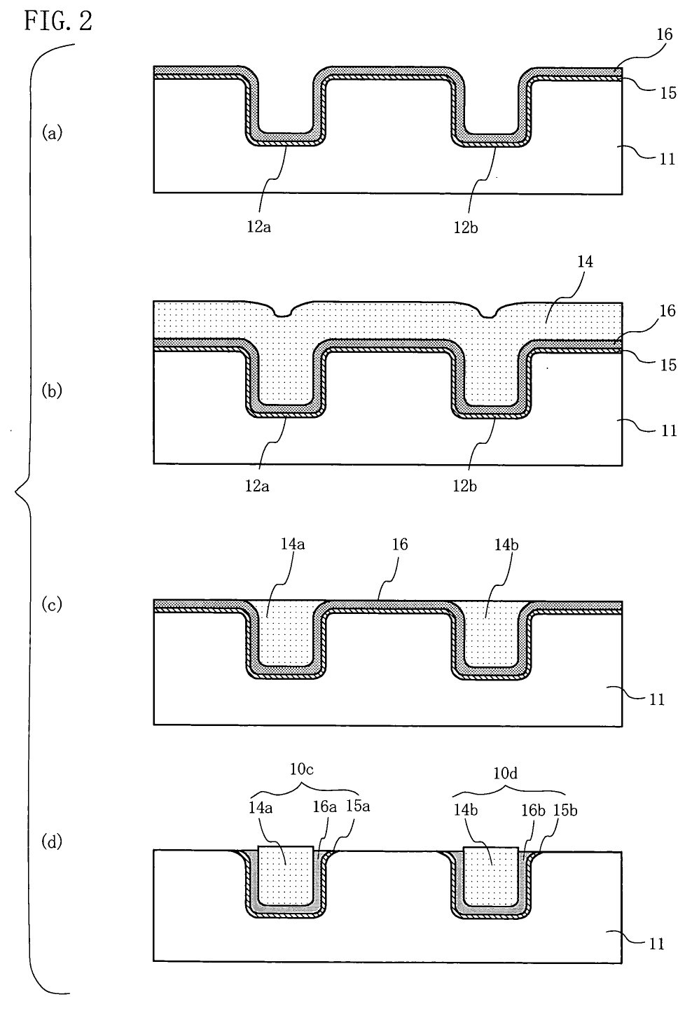

FIG. 2 shows sectional views of a silicon substrate at respective steps where element isolation portions in a STI structure are formed. FIG. 2(a) shows a sectional view where as the first insulating film, the first silicon oxide film 15 having contact with the inner walls of the trenches 12a and 12b and the second silicon-rich silicon oxide film 16 formed on this first silicon oxide film has been formed so as to cover an entire surface of the silicon substrate 11 with the trenches 12a and 12b formed thereon. In order to obtain the silicon substrate 11 in this state, first as similarly at the step shown in FIG. 1(a), the trenches 12a and 12b are formed on a principal surface of the silicon substrate 11.

Next, by using thermal oxidation, the silicon oxide film 15 having a film thickness of 15 nm is formed on the entire surface of the silicon substrate 11. The first silicon oxide film 15, which features the present embodiment, enhances adhesion with the second silicon-rich silicon oxide film 16 and reduces defects of the silicon substrate 11, which may occur when forming the trenches 12a and 12b. By providing the first silicon oxide film 15, bordering edges between the trenches 12a and 12b and the principal surface of the silicon substrate 11 and corners at the bottoms of the trenches 12a and 12b can be rounded off by oxidization, resulting in effects of alleviating stress concentration and electric field concentration which may occur on these portions.

Next, as similarly at the step shown in FIG. 1(a), the second silicon-rich silicon oxide film 16 having a film thickness of 15 nm is formed on the first silicon oxide film 15.

And as shown in FIGS. 2(b) and 2(c), a forming step and a planarization step of a silicon oxide film 14 are performed as similarly in the first embodiment. Further, etching is performed on the first silicon oxide film 15 and the second silicon-rich silicon oxide film 16 which have been formed on the principal surface of the silicon substrate 11, as similarly in the first embodiment. Thereby an inner portion of the trenches 12a is filled with a first silicon oxide film 15a, a second silicon-rich silicon oxide film 16a, and a silicon oxide film 14a, forming an element isolation portion 10c. Similarly, an inner portion of the trench 12b is filled with a first silicon oxide film 15b, a second silicon-rich silicon oxide film 16b, and a silicon oxide film 14b, forming an element isolation portion 10d.

According to the present embodiment, as described above, the first insulating film is of the laminated structure comprising the first silicon oxide film 15 and the second silicon-rich silicon oxide film 16, whereby crystal defects on side walls and bottom portions of the trenches 12a and 12b can be reduced by the first silicon oxide film 15 and moreover, adhesion with the second silicon oxide film 16 can be enhanced, reducing a leak current and realizing a more highly reliable semiconductor device than that of the first embodiment. In addition, the bordering edges between the trenches 12a and 12b and the surface of the silicon substrate 11 and the corners at the bottoms of the trenches 12a and 12b can be rounded off by oxidization, alleviating stress concentration and electric field concentration, whereby more highly reliable gate oxide film than that of the first embodiment, when forming a MOS-type transistor, can be formed. Further, because substantially mortar-shaped openings of the trenches 12a and 12b can be formed, allowing even the openings having smaller opening widths to be buried, thereby realizing a more miniaturized semiconductor device.

### Third Embodiment

Hereinafter, a method for manufacturing a semiconductor device according to a third embodiment of the present invention will be described with reference to a specific example. In the present embodiment, the method for manufacturing the semiconductor device in which a silicon oxide film whose surface alone is silicon-rich, instead of the silicon-rich silicon oxide film 13 according to the first embodiment, is used as a first insulating film will be described. Since a structure of the semiconductor device in the present embodiment has a substantially same structure of the semiconductor device according to the fist embodiment, only differences between the first and third embodiments will be described hereinafter.

The silicon oxide film whose surface or a portion in vicinity to the surface is silicon rich can be formed by continuously changing flow rates of a silane gas and an oxygen gas when forming the silicon-rich silicon oxide film 13 at the step shown in FIG. 1(a). Specifically, upon starting a film formation process of the silicon oxide film, a flow rate of the silane gas is approximately 20 sccm and a flow rate of the oxygen gas is approximately 80 sccm, and as the film formation process proceeds, the flow rates are continuously changed. And upon finishing the film formation, the flow rates are respectively controlled so that the flow rate of the silane gas is approximately 50 sccm and the flow rate of the oxygen gas is approximately 50 sccm. During this film formation process, film formation conditions other than conditions of the controlled flow rates are not changed. For example, approximately 100 sccm of flow rate of an argon gas, approximately 0.3 Pa of pressure in a reaction chamber, and approximately 400 degrees C. of film forming temperature are maintained, and 2000 W of microwave output and 2000 W of high-frequency power are supplied. Thereby whereas the silicon substrate 11 side is of an ordinary silicon oxide film, the surface side is of a silicon-rich oxide film.

And forming, planarizing, and etching of a silicon oxide film 14 shown in FIG. 1(b) to 1(d) are performed similarly to those in the first embodiment, thereby forming element isolation regions.

According to the present embodiment, similarly in the second embodiment, the first insulating film is of a silicon oxide film whose surface or a portion in vicinity to the surface is silicon-rich, whereby the ordinary silicon oxide film has contact with inner walls of the trenches 12a and 12b, alleviating stress on side walls and bottom portions of the trenches 12a and 12b, suppressing crystal defects of the silicon substrate 11, reducing a leak current. Thus more highly reliable semiconductor device than that of the first embodiment can be realized. And because the silicon oxide film whose surface or a portion in vicinity of the surface alone is silicon rich can be formed only by changing composition of reaction gases in the same reaction chamber, the silicon oxide film whose surface or a portion in vicinity to the surface alone are silicon rich can be formed in substantially same time as required in forming the silicon-rich silicon oxide film 13 according to the first embodiment.

In the present embodiment, although the method by changing the flow rates of the silane gas and the oxygen gas in a continuous manner is described, needless to say, similar effects can be obtained through realizing a laminated structure of an ordinary silicon oxide film and a silicon-rich silicon oxide film, formed by changing the flow rates of the silane gas and the oxygen gas in a phased manner.

### Fourth Embodiment

Hereinafter, a method for manufacturing a semiconductor device according to a fourth embodiment of the present invention will be described with reference to a specific example. In the present embodiment, as a first insulating film, the semiconductor device comprising a silicon-rich silicon oxide film formed by an ion-implantation technique will be described. Since a structure of the semiconductor device in the present embodiment has a substantially same structure of the semiconductor device according to the first embodiment, only differences between the first and fourth embodiments will be described hereinafter.

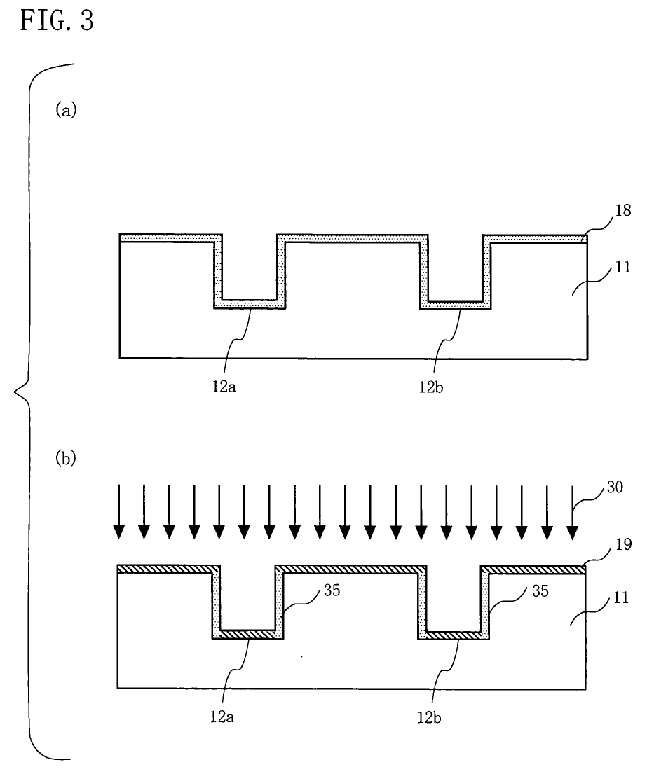

FIG. 3 shows schematic diagrams illustrating a method for forming a silicon-rich silicon oxide film according to the present embodiment. FIG. 3(a) shows a sectional view where an ordinary silicon oxide film 18 having a film thickness of 20 nm is formed as a first insulating film so as to cover an entire surface of a silicon substrate 11 having trenches 12a and 12b formed thereon. A method for forming the silicon oxide film 18 is not limited to a specific method, and thermal oxidation, high-density plasma CVD, thermal CVD or the like can be employed.

FIG. 3(b) shows a sectional view where a silicon ion 30 is implanted on the silicon oxide film 18 by using the ion implantation technique. The silicon ion 30 is implanted on a surface of the silicon oxide film 18 under conditions of 5 to 50 Kev of an energy amount and 1×10¹⁰ to 1×10¹⁵ of a dosage. An angle of implanting the silicon ion 30 is preferably perpendicular to the silicon substrate 11. Thereby the silicon ion 30 is implanted on the silicon oxide film 18 except side walls 35 of the trenches 12a and 12b, forming a silicon oxide film 19 in which only a principal surface of the silicon substrate 11 and bottom portions of the trenches 12a and 12b are slicon-rich.

And forming, planarizing, and etching of a silicon oxide film 14 shown in FIG. 1(b) to 1(d) are performed similarly to those in the first embodiment, thereby forming element isolation regions.

As described above, according to the present embodiment, because the silicon oxide film 19 as the first insulating film is not silicon-rich on the side walls 35 of the trenches 12a and 12b, stress exerted on the side walls 35 can be alleviated, suppressing crystal defects on the silicon substrate 11 and reducing a leak current, as similarly in the second and third embodiment. Thus more highly reliable semiconductor device than that of the first embodiment can be realized.

Although the respective embodiment are described with reference to specific examples, the above described specific examples are just examples of the present invention and an each depth of the trenches, film thicknesses of the first and second insulating films, film formation conditions or the like can be altered in an appropriate manner.

While the invention has been described in detail, the foregoing description is in all aspects illustrative and not restrictive. It is understood that numerous other modifications and variations can be devised without departing from the scope of the invention.

What is claimed is:

1. A method for manufacturing a semiconductor device, comprising steps of:
forming trenches on a principal surface of a semiconductor substrate;
forming a first insulating film on an entire surface of the semiconductor substrate including the trenches so as not to bury the trenches;
forming a second insulating film, burying the trenches and covering the principal surface of the semiconductor substrate, on the first insulating film; and
planarizing a surface of the second insulating film by polishing a surface of the second insulating film until the first insulating film formed on the principal surface of the semiconductor substrate is exposed, wherein
the step of forming the first insulating film forms a silicon oxide film whose surface or a portion in vicinity to the surface is silicon-rich, and
the step of forming the second insulating film forms a silicon oxide film.

2. The method for manufacturing the semiconductor device according to claim 1, wherein the step of forming the first insulating film forms the silicon oxide film so that a composition ratio of silicon is reduced in a continuous or phased manner from the surface thereof toward the surface of the semiconductor substrate.

3. The method for manufacturing the semiconductor device according to claim 1, wherein the step of forming the first insulating film comprises a step of forming a first silicon oxide film having contact with inner walls of the trenches and a step of forming a second silicon-rich oxide film on the first silicon oxide film.

4. The method for manufacturing the semiconductor device according to claim 1, wherein the step of forming the first insulating film comprises a step of forming a silicon oxide film and a step of implanting silicon ions on a surface of the silicon oxide film.

5. The method for manufacturing the semiconductor device according to claim 1, wherein the step of forming the first insulating film is performed, while applying a high-frequency power on the semiconductor substrate by using high-density plasma CVD.

6. The method for manufacturing the semiconductor device according to claim 1, wherein the step of forming the first insulating film is performed by using thermal CVD.

7. The method for manufacturing the semiconductor device according to claim 1, comprising the step of removing, using a mixed solution of hydrofluoric acid and nitric acid, the first insulating film exposed on the surface of the semiconductor substrate after the step of planarizing the surface of the second insulating film.

8. A semiconductor device comprising:
a semiconductor substrate;
a plurality of elements formed on a principal surface of the semiconductor substrate;
trenches, for element-isolating adjacent elements respectively, formed on the principal surface of the semiconductor substrate; and
element isolation portions formed by burying an insulating film in the trenches, wherein
the insulating film comprises a silicon oxide film, as a first insulating film, whose surface or a portion in vicinity to the surface is silicon-rich and is formed so as not to bury the trenches and a silicon oxide film, as a second insulating film, formed so as to bury the trenches and cover the principal surface of the semiconductor substrate.

9. The semiconductor device according to claim 8, wherein in the first insulating film, a composition ratio of silicon is reduced in a continuous or phased manner from the surface thereof toward the surface of the semiconductor substrate.

10. The semiconductor device according to claim 8, wherein the first insulating film comprises a first silicon oxide film formed so as to have contact with inner walls of the trenches and a second silicon oxide film which is formed on the first silicon oxide film and whose surface or the portion in vicinity to the surface is silicon-rich.
